(19) United States
(12) Patent Application Publication
(10) Pub. No.: US 2026/0354168 A1
(43) Pub. Date: Nov. 5, 2026

(54) CAPACITOR STRUCTURE AND METHOD OF FORMING THE SAME

(71) Applicant: Taiwan Semiconductor Manufacturing Company, Ltd., Hsinchu (TW)

(72) Inventors: Meng-Hsien Lin, Tainan City (TW); Kuan-Hua Lin, New Taipei City (TW); Hsing-Chih Lin, Tainan City (TW); Jen-Cheng Liu, Hsin-Chu City (TW); Dun-Nian Yaung, Taipei City (TW)

(21) Appl. No.: 19/196,023

(22) Filed: May 1, 2025

(51) Int. Cl. H10W 20/40; H10D 1/00; H10D 1/68

(52) U.S. Cl. CPC H10W 20/496; H10D 1/042; H10D 1/696; H10D 1/714; H10D 1/716

(57) ABSTRACT

The present disclosure, in some embodiments, relates to an integrated chip that includes a dielectric structure over a substrate. The dielectric structure includes a first plurality of dielectric layers alternatingly stacked with a second plurality of dielectric layers alternatingly. The dielectric structure has a plurality of lateral surfaces that at least partially define a plurality of lateral recesses vertically aligned with the first plurality of dielectric layers. A capacitor structure is arranged on the plurality of lateral surfaces and includes a first conductive layer, a second conductive layer, and a capacitor dielectric layer between the first and second conductive layers. An etch stop structure is in the dielectric structure and vertically extends from a top surface of the dielectric structure to a bottom dielectric layer in the first plurality of dielectric layers. The etch stop structure laterally wraps around the capacitor structure and abuts the plurality of lateral surfaces.

### BACKGROUND

Integrated chips are formed on a semiconductor die comprising millions or billions of transistor devices. The transistor devices are configured to act as switches and/or to produce power gains so as to enable logical functionality for an integrated chip (e.g., form a processor configured to perform logic functions). Integrated chips also comprise passive devices, such as capacitors, resistors, inductors, varactors, etc. Passive devices are widely used to control integrated chip characteristics, such as gains, time constants, etc.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of various features may be arbitrarily increased or reduced for clarity of discussion.

FIG. 1 illustrates a cross-sectional view of some embodiments of an integrated chip having a capacitor structure disposed within a trench of a dielectric structure and an etch stop structure in the dielectric structure and around the trench.

FIGS. 2A-2B illustrate top views of some embodiments of the integrated chip of FIG. 1.

FIGS. 3A-3B illustrate cross-sectional views of some additional embodiments of integrated chips having a capacitor structure disposed within a trench of a dielectric structure and an etch stop structure in the dielectric structure and around the trench.

FIG. 3C illustrates a cross-sectional view of some embodiments of an integrated chip comprising a plurality of capacitor structures in a plurality of trenches of a dielectric structure and a plurality of etch stop structures in the dielectric structure and around the trenches.

FIG. 4 illustrates a cross-sectional of some other embodiments of the integrated chip of FIG. 1.

FIG. 5 illustrates a cross-sectional view of some additional embodiments of an image sensor integrated chip having a capacitor structure disposed within a trench of a dielectric structure and an etch stop structure in the dielectric structure and around the trench.

FIGS. 6-19 illustrate cross-sectional views of some embodiments of a method of forming an integrated chip having a capacitor structure disposed within a trench of a dielectric structure and an etch stop structure in the dielectric structure and around the trench.

FIG. 20 illustrates a flow diagram of some embodiments of a method of forming an integrated chip having a capacitor structure disposed within a trench of a dielectric structure and an etch stop structure in the dielectric structure and around the trench.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor is a passive device that may be utilized in a wide variety of integrated chip applications. For example, a complementary metal-oxide semiconductor (CMOS) image sensor (CIS) may include lateral overflow integration capacitors (LOFICs) that may increase a high dynamic range (HDR) of the CIS. A capacitor includes a capacitor dielectric between a first conductive electrode and a second conductive electrode. A capacitance of the capacitor is directly proportional to an overlapping area between the first and second conductive electrodes. To achieve capacitances for integrated chip applications, a footprint of the capacitors may be relatively large and consume a large area over a substrate of an integrated chip. As minimum feature sizes of integrated chips are scaled down, a capacitor is not able to scale its size without reducing its capacitance.

In an effort to increase capacitance while maintaining or reducing a footprint of a capacitor, the capacitor may be formed in a trench of a dielectric structure having a plurality of lateral surfaces. The dielectric structure includes a first plurality of dielectric layers interleaved between a second plurality of dielectric layers. The first plurality of dielectric layers have a different etching selectivity than the second plurality of dielectric layers. The plurality of lateral surfaces define a plurality of lateral recesses that extend from a middle region of the trench and are arranged at different vertical heights aligned with the first plurality of dielectric layers. The capacitor lines the plurality of lateral surfaces and has a relatively large overlapping area between its conductive electrodes (e.g., compared to a capacitor formed in a trench with straight sidewalls), thereby increasing the capacitance of the capacitor. During fabrication, the plurality of lateral surfaces may be formed by a wet etch process. However, local loading effect and/or flow field variations during the wet etch process can cause inconsistent etching of the dielectric structure across the height of the trench. For instance, upper layers in the first plurality of dielectric layers may be over-etched compared to lower layers in the first plurality of dielectric layers, thereby resulting in an undesirable and unpredictable narrowing of the trench. This may cause a large variation of widths of the plurality of lateral recesses across the height of the trench, and adversely affect formation and/or performance of the capacitor. For example, the capacitor may be prone to delamination in certain regions of the trench (e.g., at relatively wide recesses that hard to properly deposit layers of the capacitor in), the capacitor may be formed with a capacitance outside of a tolerance of a predefined capacitance value, and/or the capacitor may be shorted to another directly adjacent capacitor. Thus, a device yield and/or performance of the integrated chip may be decreased.

The present disclosure relates to an integrated chip including a capacitor structure disposed within a trench of a dielectric structure and an etch stop structure laterally wrapped around the capacitor structure in the trench. The dielectric structure includes a first plurality of dielectric layers interleaved between a second plurality of dielectric layers. The trench of the dielectric structure is defined, at least in part, by a plurality of lateral surfaces that define a plurality of lateral recesses vertically aligned with the first plurality of dielectric layers. The etch stop structure vertically extends from a top surface of the dielectric structure to a bottom dielectric layer of the dielectric structure. The trench is disposed between inner opposing sidewalls of the etch stop structure, where outer points of the plurality of lateral recesses are defined by a corresponding sidewall in the inner opposing sidewalls. The capacitor structure comprises first and second electrodes separated by a capacitor dielectric. The capacitor structure is disposed in the trench and extends from the plurality of lateral surfaces to the inner opposing sidewalls of the etch stop structure. During fabrication of the capacitor structure, the etch stop structure is formed in the dielectric structure and an etch (e.g., a wet etch) is subsequently performed on the dielectric structure to form the plurality of lateral surfaces defining the trench. The etch stop structure mitigates over etching (e.g., over etching in the lateral direction) of the first plurality of dielectric layers. As a result, the plurality of lateral recesses vertically aligned with the first plurality of dielectric layers have a more uniform width across a height of the trench. This mitigates unpredictable narrowing of the capacitor structure across the height of the trench and facilitates controlling a size of the capacitor structure. Therefore, the capacitor structure may be formed with a predicable size and issues due to over etching may be mitigated, thereby increasing a performance of integrated chip.

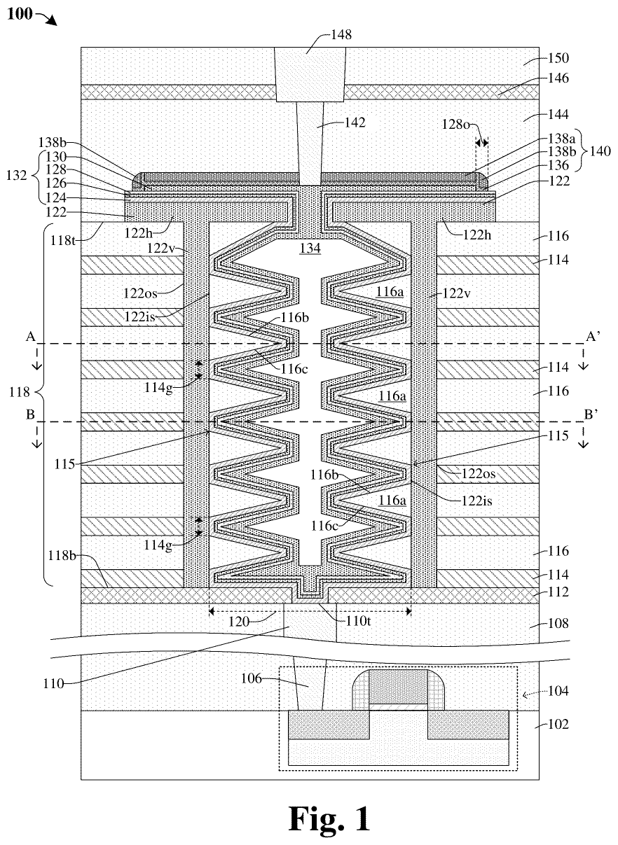

FIG. 1 illustrates a cross-sectional view 100 of some embodiments of an integrated chip having a capacitor structure 132 disposed within a trench 120 of a dielectric structure 118 and an etch stop structure 122 in the dielectric structure 118 and around the trench 120.

In some embodiments, the integrated chip comprises a transistor 104 disposed on a substrate 102. A lower inter-level dielectric (ILD) structure 108 is disposed over the substrate 102. A first via 106 and lower conductive structure 110 are disposed within the lower ILD structure 108. A lower etch stop layer 112 is disposed over the lower ILD structure 108. A dielectric structure 118 is disposed over the lower ILD structure 108. The dielectric structure 118 comprises a first plurality of dielectric layers 114 and a second plurality of dielectric layers 116 interleaved between the first plurality of dielectric layers 114. The second plurality of dielectric layers 116 comprise a plurality of lateral protrusions 116a vertically stacked over one another. The lateral protrusions 116a comprises a plurality of lateral surfaces 116b, 116c. A trench 120 is arranged in the dielectric structure 118 and extends from a top surface 118t of the dielectric structure 118 to a top surface 110t of the lower conductive structure 110. The plurality of lateral surfaces 116b, 116c at least partially define a plurality of lateral recesses 115 of the trench 120 that extend outward from a middle region of the trench 120. The plurality of lateral recesses 115 are vertically separated from one another and are aligned with a corresponding layer in the first plurality of dielectric layers 114. The first plurality of dielectric layers 114 has a first etching rate when etched with an etchant that is greater than a second etching rate of the second plurality of dielectric layers 116 when etched with the etchant. his allows a wet etch process utilizing the etchant to form the plurality of lateral protrusions 116a and to remove the first plurality of dielectric layers 114 from within the trench 120.

A capacitor structure 132 is disposed within the trench 120 and comprises a diffusion barrier layer 124, a first conductive layer 126, a capacitor dielectric layer 128, and a second conductive layer 130. The capacitor structure 132 lines the trench 120 and is disposed along the plurality of lateral surfaces 116b, 116c. The capacitor structure 132 comprises a plurality of protrusions arranged on opposing sides of the capacitor structure 132 and in the plurality of lateral recesses 115. Because the capacitor structure 132 is disposed along the plurality of lateral surfaces 116b, 116c, the surface area of the capacitor structure 132 is increased (e.g., increased relative to another capacitor structure having continuous straight sidewalls), thereby increasing a capacitance of the capacitor structure 132 within a fixed vertical distance defined by a height of the trench 120.

An etch stop structure 122 is arranged in the dielectric structure 118. In some embodiments, the etch stop structure 122 vertically extends from the top surface 118t of the dielectric structure 118 to a bottom surface 118b of the dielectric structure 118. The etch stop structure 122 laterally wraps around the trench 120. The capacitor structure 132 extends from the lateral surfaces 116b, 116c of the second plurality of dielectric layers 116 to inner sidewalls 122is of the etch stop structure 122. The plurality of lateral protrusions 116a each extend from a corresponding inner sidewall 122is of the etch stop structure 122 towards the middle region of the trench 120. A plurality of gaps 114g are arranged along the inner sidewalls 122is of the etch stop structure 122 and are interleaved between the plurality of lateral protrusions 116a. A height of an individual gap of the plurality of gaps 114g is defined by a thickness of adjacent dielectric layer of the first plurality of dielectric layers 114 that abuts an outer sidewall 122os of the etch stop structure 122. A maximum thickness of an individual lateral protrusion in the plurality of lateral protrusions 116a is defined by a thickness of an adjacent dielectric layer of the second plurality of dielectric layers 116 that abuts the outer sidewall 122os of the etch stop structure 122. In some embodiments, the etch stop structure 122 comprises a conductive material (e.g., titanium nitride).

During fabrication of the integrated chip, the etch stop structure 122 is formed in the dielectric structure 118. An initial opening is formed in the dielectric structure 118 between the inner sidewalls 122is of the etch stop structure 122, where the initial opening may define a middle region of the trench 120. A wet etch is performed on the dielectric structure 118, thereby expanding the initial opening and defining the trench 120. The first plurality of dielectric layers 114 are etched more quickly than the second plurality of dielectric layers 116 during the wet etch, thereby defining the plurality of lateral surfaces 116b, 116c and the plurality of lateral recesses 115. The etch stop structure 122 has a significantly lower etching rate than that of both the first plurality of dielectric layers 114 and the second plurality of dielectric layers 116 during the wet etch, thereby preventing issues (e.g., issues due to local loading effect and/or flow field variations during the wet etch) that may lead to lateral over-etching. For example, the etch stop structure 122 prevents etching of the first plurality of dielectric layers 114 in regions outside of the outer sidewalls 122os of the etch stop structure 122 during the wet etch. Thus, the etch stop structure 122 mitigates over-etching during the wet etch and confines the trench 120 within the inner sidewalls 122is of the etch stop structure 122. As a result, the capacitor structure 132 may be deposited in the trench 120 with a uniform profile. Therefore, the capacitor structure 132 has a relatively high capacitance and is formed with a predictable size, thereby improving an overall performance of the integrated chip.

In some embodiments, the etch stop structure 122 comprises a conductive material and is electrically coupled to the first conductive layer 126 and the lower conductive structure 110. In some embodiments, the capacitor structure 132 comprises one or more interior surfaces defining a cavity 134. A horizontal segment 122h of the etch stop structure 122 laterally extends across the top surface 118t of the dielectric structure 118 in a direction facing away from the trench 120 and in a direction towards of the trench 120. An upper portion of the capacitor structure 132 overlies the horizontal segment 122h of the etch stop structure 122. A capping structure 140 is disposed above the dielectric structure 118 and overlies the capacitor structure 132. The capping structure comprises a first passivation layer 136, a second passivation layer 138a, and a sidewall spacer 138b. The first passivation layer 136 is disposed along the second conductive layer 130 and along an offset 128o overlying the capacitor dielectric layer 128 where the second conductive layer 130 is offset inwardly towards the trench 120. The second passivation layer 138a is disposed along a first segment of the first passivation layer 136 that overlies the second conductive layer 130. The sidewall spacer 138b is disposed along a second segment of the first passivation layer 136 overlying the offset 128o.

A first upper dielectric layer 144 overlies the capping structure 140 and the dielectric structure 118. An upper etch stop layer 146 overlies the first upper dielectric layer 144 and a second upper dielectric layer 150 overlies the upper etch stop layer 146. An upper interconnect via 142 is disposed within the first upper dielectric layer 144 and is coupled to the second conductive layer 130. An upper interconnect wire 148 is disposed within the second upper dielectric layer 150 and is coupled to the upper interconnect via 142.

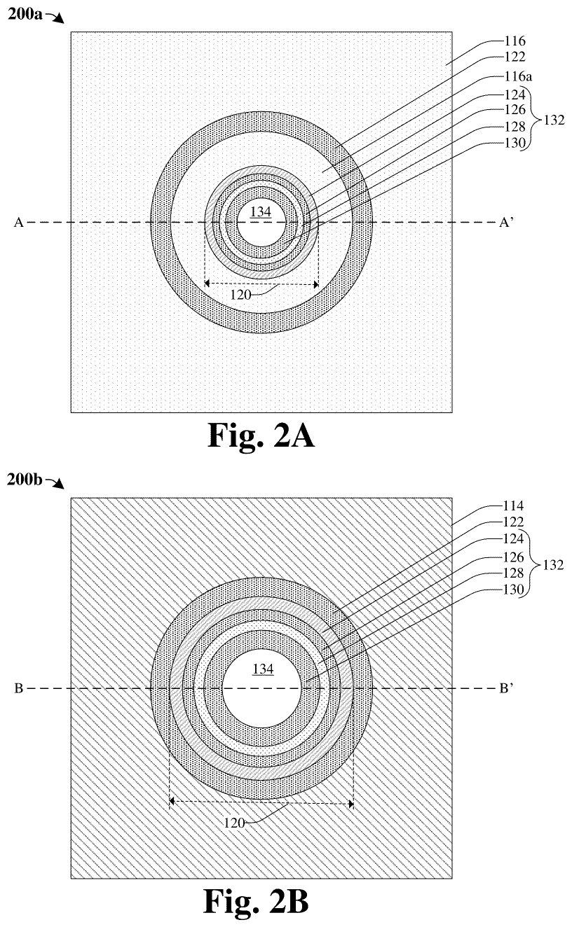

FIGS. 2A-2B illustrate top views 200a and 200b of some embodiments of the integrated chip of FIG. 1. FIG. 2A illustrates the top view 200a taken along line A-A′ of FIG. 1. FIG. 2B illustrates the top view 200b taken along line B-B′ of FIG. 1.

As shown in the top view 200a, along a plane of cutline A-A', the trench 120 is defined by a lateral protrusion 116a that laterally surrounds the trench 120 in a closed loop. In some embodiments, the lateral protrusion 116a is disposed along an inner perimeter of the etch stop structure 122 that laterally surrounds the lateral protrusion 116a in a closed loop. In some embodiments, the lateral protrusion 116a comprises a same material as one of a second plurality of dielectric layers 116 that is disposed along an outer perimeter of the etch stop structure 122. In some embodiments, the diffusion barrier layer 124, the first conductive layer 126, the capacitor dielectric layer 128, and the second conductive layer 130 are each ring shaped when viewed in top view and may, for example, be concentric with one another. In some embodiments, the etch stop structure 122 is ring shaped and extends around a perimeter of the capacitor structure 132 in top view. The second conductive layer encloses the cavity 134.

As shown in top view 200b, along the plane of cutline B-B', an inner perimeter of the etch stop structure 122 laterally wraps around the capacitor structure in a closed loop. In some embodiments, the diffusion barrier layer 124 of the capacitor structure 132 contacts the etch stop structure 122.

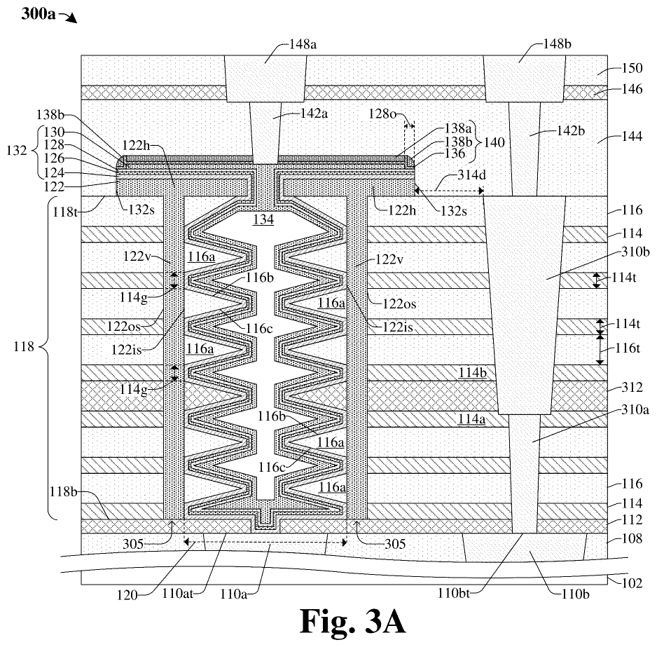

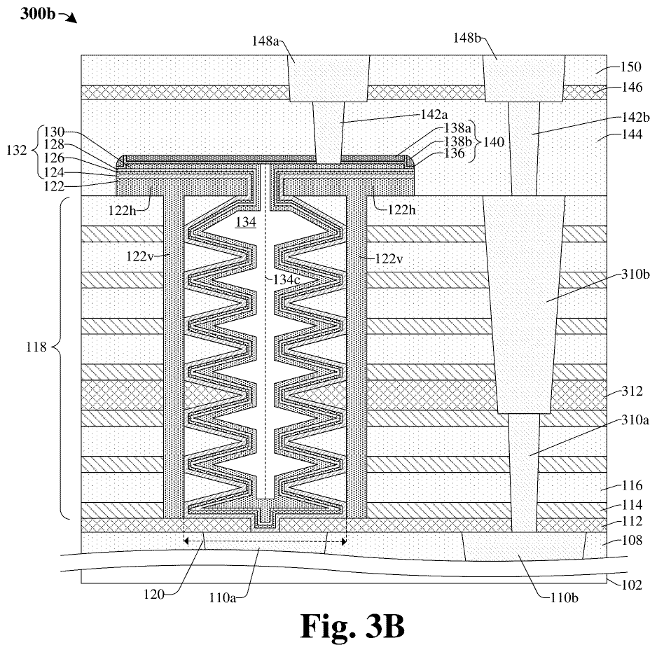

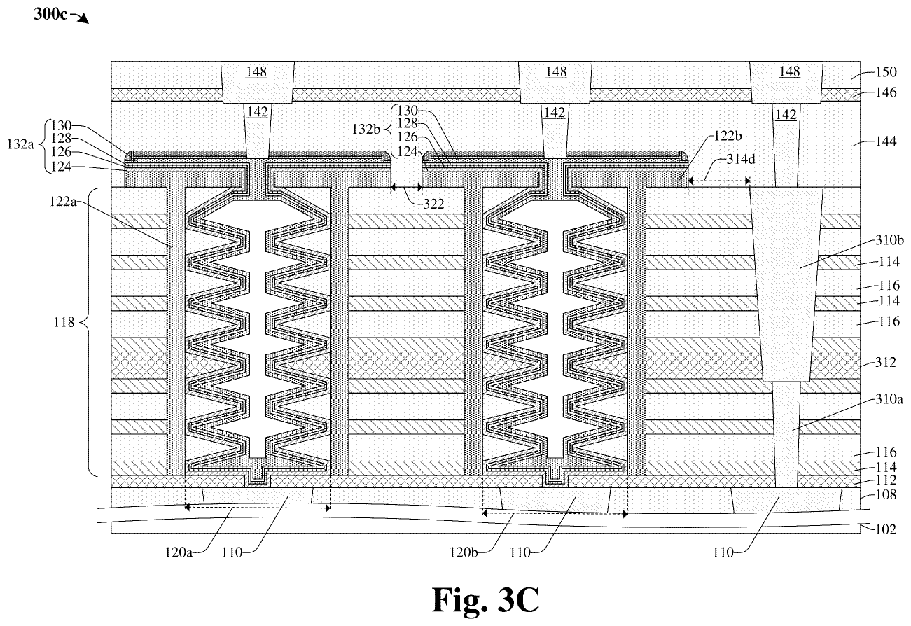

FIG. 3A illustrates a cross-sectional view 300a of some additional embodiments of an integrated chip having a capacitor structure 132 disposed within a trench 120 of a dielectric structure 118 and an etch stop structure 122 in the dielectric structure 118 and around the trench 120.

The integrated chip comprises a lower ILD structure 108 disposed over a substrate 102. In some embodiments, a plurality of lower conductive structures 110a, 110b are disposed within the ILD structure 108. In some embodiments, the plurality of lower conductive structures 110a, 110b may comprise one or more of copper, tungsten, ruthenium, aluminum, titanium nitride, tantalum nitride, or the like. A lower etch stop layer 112 is disposed over the lower ILD structure 108. In some embodiments, the lower etch stop layer 112 may comprise a nitride (e.g., silicon nitride), a carbide (e.g., silicon carbide), or the like. A dielectric structure 118 is disposed over the lower ILD structure 108 and overlies the lower etch stop layer 112. In some embodiments, the dielectric structure 118 may have a thickness within a range of about 500 nm to 3 microns or some other suitable value. The dielectric structure 118 comprises a first plurality of dielectric layers 114 and a second plurality of dielectric layers 116 interleaved between the first plurality of dielectric layers 114. In some embodiments, the first plurality of dielectric layers 114 may comprise a nitride (e.g., silicon nitride, silicon oxynitride, etc.), a carbide (e.g., silicon carbide), boron silicate glass (BSG), borophosphosilicate glass (BPSG), or the like. In some embodiments, the second plurality of dielectric layers 116 may comprise an oxide, undoped silicate glass (USG), phosphosilicate glass (PSG), or the like. In some embodiments, the first plurality of dielectric layers 114 may have thicknesses 114t within a range of about 50 nm to 200 nm, within a range of about 50 nm to 100 nm, within a range of about 100 nm to 200 nm, or some other suitable value. In some embodiments, the second plurality of dielectric layers 116 may have thicknesses 116t within a range of about 100 nm to 600 nm, within a range of about 100 nm to 350 nm, within a range of about 350 nm to 600 nm, or some other suitable value. In some embodiments, the thicknesses 114t of the first plurality of dielectric layers 114 are less than the thickness 116t of the second plurality of dielectric layers 116.

An etch stop structure 122 is disposed within vertical openings 305 that extend from a top surface 118t of the dielectric structure 118 to a bottom surface 118b of the ILD structure 108. In some embodiments, the etch stop structure 122 comprises a pair of vertical segments 122v and a pair of horizontal segments 122h over the horizontal segments 122h. The vertical segments 122v are arranged in the vertical openings 305 on opposing sides of a trench 120 arranged in the dielectric structure 118. The etch stop structure 122 separates an inner segment of the dielectric structure 118 from an outer segment of the dielectric structure 118, where the inner segment of the dielectric structure 118 is arranged between a pair of inner sidewalls 122is of the etch stop structure 122 and the outer segment of the dielectric structure 118 is arranged outside a pair of outer sidewalls 122os of the etch stop structure 122. In some embodiments, the vertical openings 305 each have a width within a range of about 100 nm to 250 nm or some other suitable value. In some embodiments, the vertical segments 122v have a height within a range of about 500 nm and 3 microns or some other suitable value. In some embodiments, the horizontal segments 122h of the etch stop structure 122 may each have a width within a range of about 50 nm to 600 nm or some other suitable value. In some embodiments, the etch stop structure 122 may, for example, comprise a nitride (e.g. titanium nitride, tantalum nitride, etc.), tantalum (Ta), tungsten (W), or the like. In various embodiments, a material of the etch stop structure 122 is different from that of the lower etch stop layer 112, the first plurality of dielectric layers 114, and the second plurality of dielectric layers 116.

In some embodiments, the pair of inner sidewalls 122is, the pair of outer sidewalls 122os, the pair of vertical segments 122v, and the pair of horizontal segments 122h are defined from a cross-sectional view. For example, when viewed from above, if the etch stop structure 122 is circular/elliptical, then the pair of vertical segments 122v is a single continuous vertical segment that is ring shaped when viewed from above, therefore the “pair” of vertical segments 122v refers to the nature of this single continuous structure when depicted in a cross-sectional view.

The trench 120 extends from a top surface 118t of the dielectric structure 118 to a top surface 110at of a first lower conductive structure 110a. In some embodiments, the trench 120 may have a thickness that is within a range of about 100 nm to 300 nm, 100 nm to 600 nm, 150 nm to 1 micron, or some other suitable value. The trench 120 is defined by a plurality of lateral surfaces 116b, 116c of the dielectric structure 118 and the inner sidewalls 122is of the etch stop structure 122. The plurality of lateral surfaces 116b, 116c may be surfaces of the second plurality of dielectric layers 116 and/or may define upper and lower surfaces of a plurality of lateral protrusions 116a. In some embodiments, the plurality of lateral protrusions 116a each extend continuously in a closed path along an inner perimeter of the etch stop structure 122 when viewed in top view. Adjacent lateral protrusions in the plurality of lateral protrusions 116a are vertically separated from one another by a vertical distance of a corresponding gap in a plurality of gaps 114g that is equal to or greater than a thickness 114t of an adjacent corresponding dielectric layer in the first plurality of dielectric layers 114. In some embodiments, the vertical distances of the plurality of gaps 114g may be within a range of about 50 nm to 200 nm or some other suitable value. In some embodiments, an individual lateral protrusion in the plurality of lateral protrusions 116a comprises a pair of lateral surfaces in the plurality of lateral surfaces 116b, 116c that extend from a corresponding sidewall in the inner sidewalls 122is of the etch stop structure 122. In some embodiments, one or more of the lateral surfaces 116b, 116c are angled at an obtuse angle measured with respect to the corresponding sidewall in the inner sidewalls 122is of the etch stop structure 122. In some embodiments, pairs of lateral surfaces in the plurality of lateral surfaces 116b, 116c each meet at a point within the trench 120 in a region laterally offset from the inner sidewalls 122is. In some embodiments, the plurality of lateral surfaces 116b, 116c may have a horizontal length within a range of about 50 nm to 400 nm or some other suitable value.

A capacitor structure 132 is disposed within the trench 120. In some embodiments, the capacitor structure 132 lines the trench 120 and extends along the plurality of lateral surface 116b, 116c and the inner sidewalls 122is of the etch stop structure 122 to the top surface 110at of a first lower conductive structure 110a. In some embodiments, the capacitor structure 132 comprises an upper segment over the horizontal segments 122h of the etch stop structure 122. The capacitor structure 132 comprises a diffusion barrier layer 124, a first conductive layer 126 disposed along the diffusion barrier layer 124, a second conductive layer 130, and a capacitor dielectric layer 128 between the first conductive layer 126 and the second conductive layer 130. In some embodiments, the capacitor structure 132 has one more interior surfaces defining a cavity 134 within the trench 120. In some embodiments, the capacitor structure 132 has opposing outer sidewalls 132s aligned with opposing sidewalls of the horizontal segments 122h of the etch stop structure 122. The capacitor structure 132 being disposed along the plurality of lateral surfaces 116b, 116c within the trench 120 increases the surface area between the first conductive layer and 126 and the second conductive layer 130 along a height of the trench 120, thereby increasing a capacitance of the capacitor structure 132. The etch stop structure 122 mitigates or prevents over etching during formation of the trench 120, such that widths of the lateral protrusions 116a across a height of the trench 120 are more uniform. As a result, the capacitor structure 132 has a uniform profile across the height of the trench 120, thereby increasing an overall performance of the integrated chip.

In some embodiments, the diffusion barrier layer 124 may, for example, be or comprise titanium nitride, tantalum nitride, tantalum, tungsten, some other suitable material, or any combination of the foregoing. The diffusion barrier layer 124 may have a thickness that is within a range of about 10 Angstroms (Å) to 1000 Å or some other suitable value. In some embodiments, the first conductive layer 126 and the second conductive layer 130 may, for example, respectively be or comprise copper, aluminum, tantalum, tungsten, titanium, tantalum nitride, titanium nitride, some other suitable material, or any combination of the foregoing. In some embodiments, the first conductive layer 126 may comprise a same metal or a different metal as the second conductive layer 130. The first conductive layer 126 and the second conductive layer 130 may respectively have a thickness that is within a range of about 10 Å to 1000 Å or some other suitable value. In some embodiments, the first conductive layer 126 may have a same thickness as the second conductive layer 130, while in other embodiments, the first conductive layer 126 may have a different thickness than the second conductive layer 130. In some embodiments, the capacitor dielectric layer 128 may, for example, be or comprise zirconium oxide, hafnium oxide, aluminum oxide, titanium oxide, silicon nitride, silicon dioxide, silicon carbide, some other suitable dielectric material, or any combination of the foregoing. The capacitor dielectric layer 128 may have a thickness that is within a range of about 5 Å to 1000 Å or some other suitable value.

A capping structure 140 is disposed above the capacitor structure 132. The capping structure 140 comprises a first passivation layer 136, a second passivation layer 138a, and a sidewall spacer 138b. The first passivation layer 136 overlies the second conductive layer 130. The second passivation layer 138a overlies the first passivation layer 136. The sidewall spacer 138b overlies the first passivation layer 136 above the offset 128o and extends continuously in a closed path around an inner sidewall of the first passivation layer 136 when viewed in top view. In a cross-section view, the sidewall spacer 138b is arranged as a pair on opposing sides of the first passivation layer 136. In some embodiments, the first passivation layer 136 may, for example, be or comprise silicon oxide or some other suitable material. In some embodiments, the second passivation layer 138a may, for example, be or comprise silicon nitride, silicon oxynitride, or some other suitable material. In some embodiments, the sidewall spacer 138b may comprise a same material as the second passivation layer 138a, in other embodiments, the sidewall spacer 138b may comprise a different material than the second passivation layer 138a.

In some embodiments, an interconnect via 310a and an interconnect wire 310b are disposed within the dielectric structure 118 at positions that are laterally separated from the trench 120 by the etch stop structure 122. In some embodiments, the interconnect wire 310b is separated from the etch stop structure 122 by a distance 314d within a range of about 100 nm to 1 micron or some other suitable value. The interconnect via 310a contacts a bottom of the interconnect wire 310b and contacts a top surface 110bt of the second lower conductive structure 110b. In some embodiments, the interconnect via 310a and/or the interconnect wire 310b respectively and vertically extend through at least two of the first plurality of dielectric layers 114 and at least two of the second plurality of dielectric layers 116.

A first upper dielectric layer 144 overlies the capping structure 140. An upper etch stop layer 146 overlies the first upper dielectric layer 144 and a second upper dielectric layer 150 overlies the upper etch stop layer 146. In some embodiments, a first upper interconnect via 142a extends through the first upper dielectric layer 144, the second passivation layer 138a, and the first passivation layer 136 to contact the second conductive layer 130 of the capacitor structure 132. A second upper interconnect via 142b extends though the first upper dielectric layer 144 to contact the interconnect wire 310b. In some embodiments, a plurality of upper interconnect wires 148a, 148b are arranged in the second upper dielectric layer 150 and overlie the first and second upper interconnect vias 142a, 142b. In some embodiments, an etch stop layer 312 is arranged within the dielectric structure 118. In some embodiments, the etch stop layer 312 may be arranged between a first dielectric layer 114a and a second dielectric layer 114b of the first plurality of dielectric layers 114. In some embodiments, a bottom surface of the interconnect wire 310b is below a top surface of the etch stop layer 312. In some embodiments, the etch stop layer 312 comprises one or more lateral protrusions between the inner sidewalls 122is of the etch stop structure 122, where the one or more lateral protrusions have a pair of lateral surfaces defining a portion of the trench 120.

FIG. 3B illustrates a cross-sectional view 300b of some other embodiments of the integrated chip of FIG. 3A, in which the first upper interconnect via 142a is laterally offset from a middle region of the capacitor structure 132. In some embodiments, the cavity 134 is defined by a plurality of interior surfaces of the second conductive layer 130 and a lower surface of the capping structure 140. In various embodiments, the first upper interconnect via 142a is laterally offset from a center 134c of the cavity 134.

FIG. 3C illustrates a cross-sectional view 300c of some embodiments of an integrated chip comprising a plurality of capacitor structures in a plurality of trenches of a dielectric structure and a plurality of etch stop structures in the dielectric structure and around the trenches.

The integrated chip comprises a substrate 102 disposed below a lower ILD structure 108 that comprises a plurality of lower conductive structures 110. A lower etch stop layer 112 overlies the lower ILD structure 108. A dielectric structure 118 overlies the lower etch stop layer 112. A plurality of trenches 120a-b are disposed within the dielectric structure 118. A plurality of capacitor structures 132a-b are disposed within the trenches 120a-b in the dielectric structure 118. A plurality of etch stop structures 122a-b are disposed in the dielectric structure 118 and are separated from one another by a distance 322. The distance 322 may, for example, be within a range of about 100 nm to 1 micron or some other suitable value. In some embodiments, a first capacitor structure 132a is disposed in a first trench 120a that is confined and/or surrounded by a first etch stop structure 122a. A second capacitor structure 132b is disposed in a second trench 120b that is confined and/or surrounded by a second etch stop structure 122b. A plurality of upper interconnect vias 142 are arranged in a first upper dielectric layer 144 and overlie the plurality of capacitor structures 132a-b and an interconnect wire 310b laterally offset from the second etch stop structure 122b. A plurality of upper interconnect wires 148 are arranged in a second upper dielectric layer 150 and overlie the plurality of upper interconnect vias 142.

By virtue of the first etch stop structure 122a laterally surrounding the first trench 120a and the second etch stop structure 122b laterally surrounding the second trench 120b, issues due to over etching during formation of the trenches 120a-b may be mitigated. For example, the etch stop structures 122a-b prevent over etching in the lateral direction during fabrication of the trenches 120a-b, such that the trenches 120a-b are isolated from one another (e.g., across at least the distance 322). Thus, the etch stop structures 122a-b confine the trenches 120a-b and facilitate proper formation of the capacitor structures 132a-b in the trenches 120a-b, thereby improving an overall performance of the integrated chip. The etch stop structures 122a-b also facilitate isolation from interconnect structures (e.g., the interconnect wire 310b) and/or other structures in the dielectric structure 118 within a close proximity to the capacitor structures 132a-b.

FIG. 4 illustrates a cross-sectional view 400 of some other embodiments of the integrated chip of FIG. 1, in which the dielectric structure 118 comprises a plurality of inner sidewalls spaced between inner sidewalls 122is of the etch stop structure 122.

In some embodiments, one or more of the protrusions in the plurality of lateral protrusions 116a comprise a first lateral surface 116b, a second lateral surface 116c, and an inner sidewall 116d between the first and second lateral surfaces 116b, 116c. In some embodiments, a width 402 of the trench 120 between a first pair of protrusions in the plurality of lateral protrusions 116a is greater than a second width 404 of the trench 120 between a second pair of protrusions in the plurality of lateral protrusions 116a. In such embodiments, the first pair of protrusions is vertically above the second pair of protrusions. In some embodiments, a first sidewall height 406 of an individual lateral protrusion in the first pair of protrusions is greater than a second sidewall height 408 of an individual lateral protrusion in the second pair of protrusions. In various embodiments, a width of the cavity 134 may decrease in a direction from a top of the cavity 134 in a direction towards the substrate 102.

In some embodiments, the plurality of lateral protrusions 116a are vertically separated from one another by a plurality of gaps 114g. The plurality of gaps 114g include a first gap 114g1 and a second gap 114g2. In some embodiments, the first gap 114g1 may have a thickness or height that is greater than the second gap 114g2. In other embodiments, the thickness or the height of the first gap 114g1 is the same as that of the second gap 114g2. In some embodiments, thicknesses of the plurality of gaps 114g may be defined by a thickness of an adjacent dielectric layer in the first plurality of dielectric layers 114 disposed along an outer sidewall of the outer sidewalls 122os of the etch stop structure 122. In other embodiments, the thicknesses of the plurality of gaps 114g may be greater that of the adjacent dielectric layer in the first plurality of dielectric layers 114. The capacitor structure 132 lines the trench 120 and conforms to shapes of the plurality of laterally protrusions 116a and fills at least portions of the gaps 114g. In some embodiments, the capacitor structure 132 comprises vertical segments continuously extending across each gap in the plurality of gaps 114g.

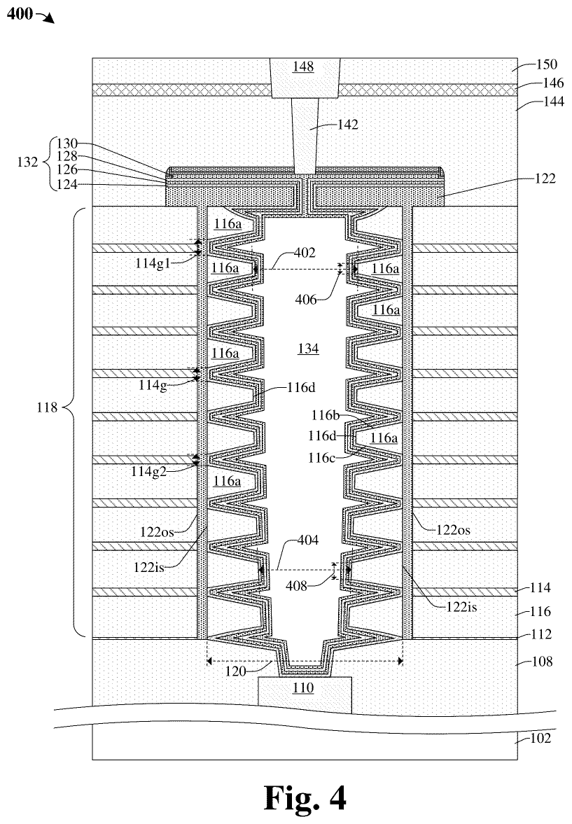

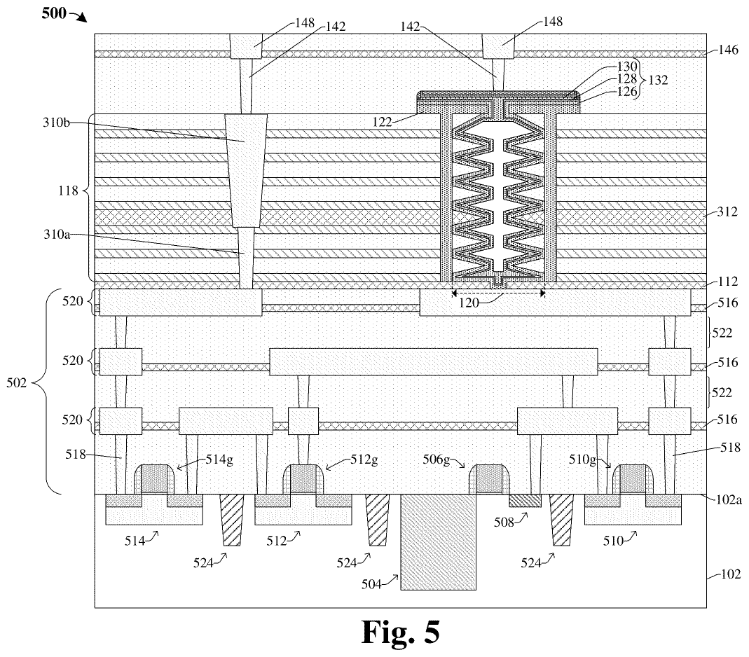

FIG. 5 illustrates a cross-sectional view 500 of some embodiments of an image sensor integrated chip having a capacitor structure 132 disposed within a trench 120 of a dielectric structure 118 and an etch stop structure 122 in the dielectric structure 118 and around the trench 120.

In some embodiments, the image sensor integrated chip comprises a lower ILD structure 502 disposed above a substrate 102. In some embodiments, the lower ILD structure 502 comprises a plurality of conducive contacts 518, a plurality of interconnect wires 520, a plurality of interconnect vias 522, a plurality of ILD etch stop layers 516, and a plurality of gate structures 506g, 510g, 512g, 514g. The plurality of ILD etch stop layers 516 are arranged at different levels of the plurality of interconnect wires 520. The ILD etch stop layers 516 may, for example, be or comprise silicon nitride, silicon carbide, silicon oxynitride, silicon oxycarbide, or the like. A lower etch stop layer 112 overlies the lower ILD structure 502 and separates a dielectric structure 118 from the lower ILD structure 502. An etch stop structure 122 is disposed within the dielectric structure 118 and laterally surrounds a trench 120 within the dielectric structure 118. A capacitor structure 132 is disposed within the trench 120, where a segment of the capacitor structure 132 in the trench is laterally confined by the etch stop structure 122. The capacitor structure 132 may be configured as a lateral overflow integration capacitor (LOFIC).

An image sensing element 504, a floating diffusion well 508, and a plurality of transistors 510, 512, 514 are arranged on and/or within the substrate 102. An isolation structure 524 is arranged in the substrate 102 between the transistors 510, 512, 514. In some embodiments, the image sensing element 504 comprises a first region having a first doping type (e.g., n-type doping) that borders a second region having a second doping type (e.g., p-type doping) that is different than the first doping type. The image sensing element 504 may, for example, be a photodiode. The plurality of gate structures 506g, 510g, 512g, 514g have a gate dielectric layer disposed along a top surface 102a of the substrate 102 and a gate electrode arranged on the gate dielectric layer. In some embodiments, sidewall spacers are arranged on opposing sides of the gate electrode.

In some embodiments, a transfer transistor gate structure 506g is disposed laterally between the image sensing element 504 and the floating diffusion well 508. The transfer transistor gate structure 506g is configured to control a transfer of charge from the image sensing element 504 to the floating diffusion well 508. The floating diffusion well 508 is coupled to a source-follower transistor gate structure 512g and a first source/drain region of a capacitor switch transistor 510. In some embodiments, the source-follower transistor 512 is coupled between a row select transistor 514 and a voltage node (e.g., a node coupled to a power supply), where the source-follower transistor configured to buffer and amplify a voltage at the floating diffusion well 508. The row select transistor 514 is configured to selectively pass a buffered and amplified voltage from the source-follower transistor 512 to an output terminal. A second source/drain region of the capacitor switch transistor 510 is coupled to the capacitor structure 132.

In some embodiments, the capacitor switch transistor 510 is configured to switch the image sensing element 504 between a low conversion gain mode and a high conversion gain mode. For example, when operating in the low conversion mode, the capacitor switch transistor 510 is closed (e.g., ON) so that the capacitor structure 132 is coupled to the floating diffusion well 508. In such instances, charge at the floating diffusion well 508 will overflow into the capacitor structure 132. When operating in the high conversion mode, the capacitor switch transistor 510 is open (e.g., OFF) so that the capacitor structure 132 is isolated from the floating diffusion well 508. The plurality of gate structures 506g, 510g, 512g, 514g, source/drain regions of the plurality of transistors 510, 512, 514, and the capacitor structure 132 are operably coupled to each other by the plurality of conducive contacts 518, the plurality of interconnect wires 520, and the plurality of interconnect vias 522. Source/drain region(s) may refer to a source or a drain, individually or collectively depending upon the context.

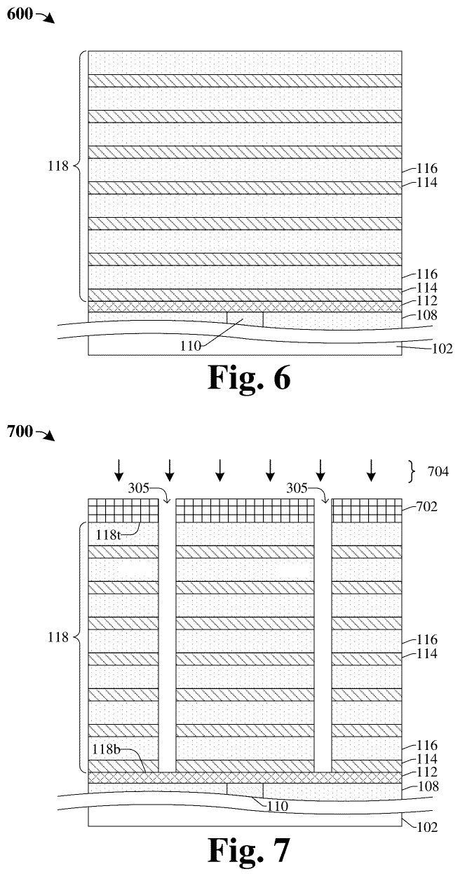

FIGS. 6-19 illustrate cross-sectional views of some embodiments of a method of forming an integrated chip having a capacitor structure disposed within a trench of a dielectric structure and an etch stop structure in the dielectric structure and around the trench. Although FIGS. 6-19 are described in relation to a method, it will be appreciated that the structures disclosed in FIGS. 6-19 are not limited to such a method, but instead may stand alone as structures independent of the method.

As shown in cross-sectional view 600 of FIG. 6, a lower ILD structure 108 and a lower conductive structure 110 are formed over a substrate 102. In some embodiments, the substrate 102 may, for example, be or comprise a bulk substrate (e.g., a bulk silicon substrate), a silicon-on-insulator (SOI) substrate, or another suitable substrate material. In some embodiments, the lower conductive structure 110 may be formed using a damascene process (e.g., a single damascene process or a dual damascene process) or some other suitable process. In such embodiments, the lower conductive structure 110 may be formed by depositing the lower ILD structure 108 over the substrate 102, selectively etching the lower ILD structure 108 to define a trench within the lower ILD structure 108, forming a conductive material (e.g., copper, aluminum, etc.) within the trench, and performing a planarization process (e.g., a chemical mechanical planarization (CMP) process) to remove excess of the conductive material from over the lower ILD structure 108.

As further shown in FIG. 6, a lower etch stop layer 112 is deposited over the lower ILD structure 108 and a dielectric structure 118 is formed over the lower etch stop layer 112. In some embodiments, the lower etch stop layer 112 may, for example, be or comprise silicon nitride, silicon carbide, silicon oxynitride, silicon oxycarbide, another suitable dielectric material, or any combination of the foregoing. In some embodiments, the dielectric structure 118 comprises a first plurality of dielectric layers 114 and a second plurality of dielectric layers 116 alternatingly stacked with the first plurality of dielectric layers 114. The first plurality of dielectric layers 114 are a first material and the second plurality of dielectric layers 116 are a second dielectric material that is different than the first material. The first material and the second material have different etching selectivities with respect to an etchant. For example, the first material may have a first etching rate when exposed to an etchant and a second material may have a second etching rate when exposed to the etchant. In some embodiments, the first plurality of dielectric layers 114 may comprise a nitride (e.g., silicon nitride, silicon oxynitride, etc.), a carbide (e.g., silicon carbide), boron silicate glass (BSG), borophosphosilicate glass (BPSG), or the like. In some embodiments, the second plurality of dielectric layers 116 may comprise an oxide, undoped silicate glass (USG), phosphosilicate glass, or the like. In some embodiments, the first plurality of dielectric layers 114 may be formed to a first thickness and the second plurality of dielectric layers 116 may be formed to a second thickness that is greater than the first thickness. In some embodiments, the first plurality of dielectric layers 114, the second plurality of dielectric layers 116, and the lower etch stop layer 112 may be formed by a plurality of deposition processes (e.g., a PVD process, a CVD process, a PE-CVD process, an ALD process, or the like).

As shown in cross-sectional view 700 of FIG. 7, a pair of vertical openings 305 is formed within the dielectric structure 118. The vertical openings 305 extends from a top surface 118t of the dielectric structure 118 to a bottom surface 118b of the dielectric structure 118, through the first plurality of dielectric layers 114 and the second plurality of dielectric layers 116. In some embodiments, in top view the vertical openings 305 are part of a single ring-shaped opening that continuously extends in a closed loop. In some embodiments, the vertical openings 305 may be formed by exposing the dielectric structure 118 to one or more etchants 704 according to a mask 702 in an etch process. In some embodiments, the one or more etchants 704 may comprise a dry etchant (e.g., a reactive ion etching (RIE) etchant, a plasma etchant, or the like). In some embodiments, the one or more etchants 704 may have an etching chemistry comprising one or more of fluorine (F), tetrafluoromethane (CF₄), ozone (O2), or octafluorocyclobutane (C₄F₈), or the like). In some embodiments, the mask 702 may comprise a photosensitive material (e.g., photoresist), a hard mask, or the like.

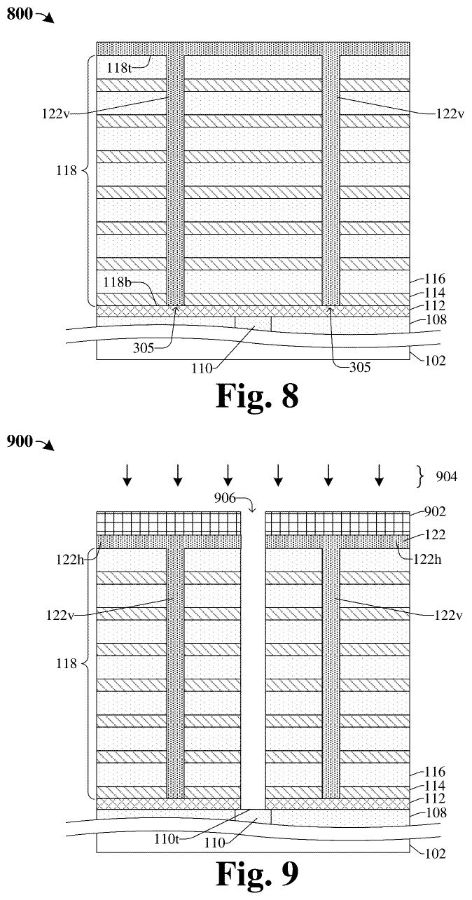

As shown in cross-sectional view 800 of FIG. 8, an etch stop structure 122 is deposited within the vertical openings 305. In some embodiments, the etch stop structure 122 overlies the dielectric structure 118 and comprises a pair of vertical segments 122v that extends from a top surface 118t of the dielectric structure 118 to a bottom surface 118b of the dielectric structure 118. In some embodiments, the etch stop structure 122 may comprise a nitride (e.g. titanium nitride), tantalum (Ta), tungsten (W), or the like. In some embodiments, the etch stop structure 122 may be formed by a plurality of deposition processes (e.g., a PVD process, a CVD process, a PE-CVD process, an ALD process, or the like).

As shown in cross-sectional view 900 of FIG. 9, an initial opening 906 is formed within the dielectric structure 118. The initial opening 906 extends to a top surface 110t of the lower conductive structure 110 through horizontal segments 122h of the etch stop structure 122, the first plurality of dielectric layers 114, the second plurality of dielectric layers 116, and the lower etch stop layer 112. In some embodiments, the initial opening 906 may be formed by exposing the dielectric structure 118 and the etch stop structure 122 to one or more etchants 904 according to a mask 902 in a dry etch process. In some embodiments, the one or more etchants 904 may comprise a dry etchant (e.g., a reactive ion etching (RIE) etchant, a plasma etchant, or the like). In some embodiments, the one or more etchants 904 may have an etching chemistry comprising one or more of fluorine (F), tetrafluoromethane (CF4), ozone (O2), or octafluorocyclobutane (C4F8), or the like). In some embodiments, the mask 902 may comprise a photosensitive material (e.g., photoresist), a hard mask, or the like.

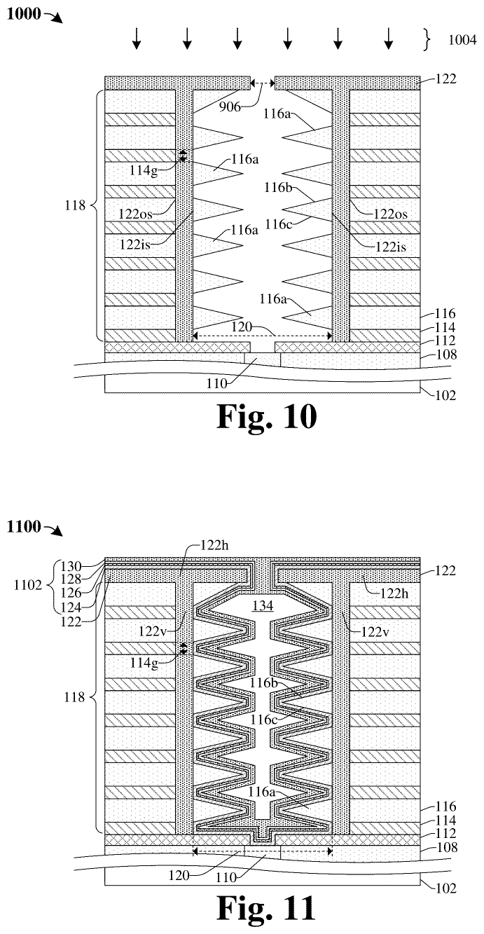

As shown in cross-sectional view 1000 of FIG. 10, a wet etching process is performed on the dielectric structure 118 to expand the initial opening 906 in the dielectric structure 118 and form a trench 120 in the dielectric structure 118. In some embodiments, the trench 120 may be referred to as an opening, a capacitor opening, or the like. The wet etching process laterally etches the first plurality of dielectric layers 114 at a different rate than the second plurality of dielectric layers 116 to form the trench 120 with opposing sides having saw-tooth profiles. The wet etching process forms a plurality of lateral protrusions 116a in the second plurality of dielectric layers 116 that have a plurality of lateral surfaces 116b, 116c. In some embodiments, regions of the first plurality of dielectric layers 114 within inner sidewalls 122is of the etch stop structure 122 are removed during the wet etching process to reveal the plurality of lateral surfaces 116b, 116c of the lateral protrusions 116a. Each of the lateral protrusions 116a are vertically spaced from each other along the inner sidewalls 122is of the etch stop structure 122 by a plurality of gaps 114g. Each of the gaps 114g have a thickness or height defined by an adjacent dielectric layer of the first plurality of dielectric layers 114 that is disposed along a corresponding outer sidewall 122os of the etch stop structure 122. In some embodiments, the trench 120 may have a substantially rectangular shape as viewed from a top-view. In other embodiments, the trench may have a substantially circular shape, a substantially square shape, or the like, as viewed from a top-view.

In some embodiments, the wet etching process may be performed by exposing the etch stop structure 122 and the dielectric structure 118 to one or more wet etchants 1004. In some embodiments, the one or more wet etchants 1004 may comprise hydrofluoric acid (HF) (e.g., liquid based HF or vapor based HF), ammonium fluoride (NH₄F), or the like. The wet etching process may be a buffered oxide etch (BOE), where the one or more wet etchants 1004 comprise a diluted hydrofluoric (HF) solution buffered with ammonium fluoride (NH₄F). In various embodiments, the one or more wet etchants 1004 may etch a nitride (e.g., silicon nitride, silicon oxynitride, etc.), a carbide (e.g., silicon carbide), boron silicate glass (BSG), borophosphosilicate glass (BPSG), and may etch an oxide, undoped silicate glass (USG), phosphosilicate glass, at a selectivity of a range of about 5:1. The wet etching process is configured to etch the first plurality of dielectric layers 114 at a first etching rate and etch the second plurality of dielectric layers 116 at a second etching rate. In various embodiments, the first etching rate is greater than the second etching rate. For example, the first etching rate is at least 5 times greater than the second etching rate. In some embodiments, the one or more wet etchants 1004 may stop on a metal nitride (e.g. titanium nitride), tantalum (Ta), tungsten (W), or the like to prevent over etching in lateral directions. In various embodiments, the etch stop structure 122 has a third etching rate during the wet etching process that is substantially less than both the first etching rate and the second etching rate. In some embodiments, the first etching rate is at least 35 times greater than the third etching rate, within a range of 35 to 100 times greater than the third etching rate, or some other suitable value. In further embodiments, the second etching rate is at least 20 to 50 times greater than the third etching rate.

The etch stop structure 122 provides a boundary to prevent lateral over etching of the first plurality of dielectric layers 114 and the second plurality of dielectric layers 116 in regions outside of the outer sidewalls 122os of the etch stop structure 122. Thus, the etch stop structure 122 mitigates or prevents issues due to lateral over etching by confining the wet etch process to a space between the inner sidewalls 122is of the etch stop structure 122, thereby increasing a uniformity of a profile of the trench 120 across a height of the trench 120.

As shown in cross-sectional view 1100 of FIG. 11, a stack of capacitor layers 1102 is formed within the trench 120 and overlies the etch stop structure 122. The stack of capacitor layers 1102 comprises a diffusion barrier layer 124, a first conductive layer 126 disposed along the diffusion barrier layer 124, a capacitor dielectric layer 128 on the first conductive layer 126, and a second conductive layer 130 on the capacitor dielectric layer 128. The capacitor dielectric layer 128 separates the first conductive layer 126 from the second conductive layer 130. Each of the layers of the stack of capacitor layers 1102 conforms to the plurality of lateral surfaces 116b, 116c and the plurality of gaps 114g within the trench 120 confined by the vertical segments 122v. In some embodiments, the stack of capacitor layers 1102 seals a cavity 134 in the trench 120. In some embodiments, the diffusion barrier layer 124, the first conductive layer 126, the capacitor dielectric layer 128, and the second conductive layer 130 may have thicknesses within a range of about 10 Angstroms (Å) to 1000 Å or some other suitable value and may be formed by way of a plurality of ALD processes, a plurality of PVD processes, a plurality of CVD processes, or the like.

As shown in cross-sectional view 1200 of FIG. 12, a first passivation layer 136 and a second passivation layer 138a are formed over the stack of capacitor layers 1102. In some embodiments, the first passivation layer 136 may comprise silicon oxide and the second passivation layer 138a may comprise silicon nitride. In some embodiments, the first passivation layer 136 and the second passivation layer 138a may each be formed by one or more deposition processes (e.g., a PVD process, a CVD process, a PE-CVD process, an ALD process, or the like).

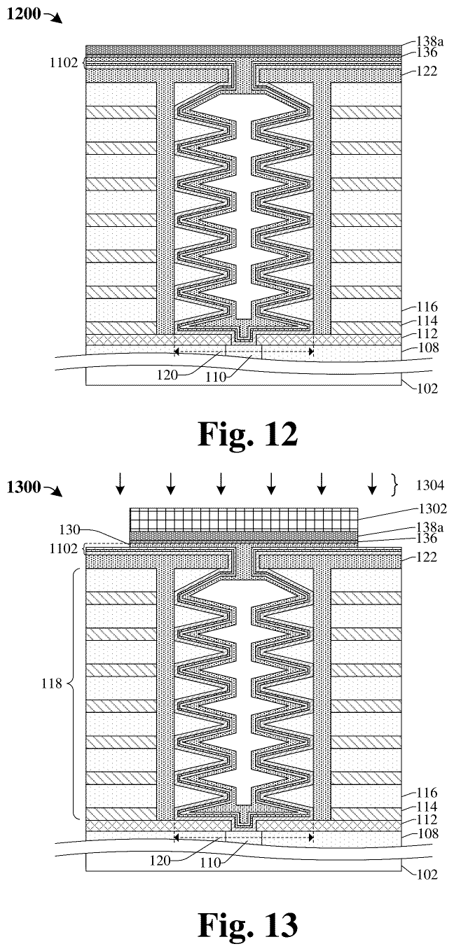

As shown in cross-sectional view 1300 of FIG. 13, an etching process is performed on the second passivation layer 138a, the first passivation layer 136, and the second conductive layer 130 of the stack of capacitor layers 1102. In some embodiments, the etching process may be performed using one or more etchants 1304 according to a mask 1302 in a dry etch process. In some embodiments, the one or more etchants 1304 may comprise a dry etchant (e.g., a reactive ion etching (RIE) etchant, a plasma etchant, or the like). In some embodiments, the one or more etchants 1304 may have an etching chemistry comprising one or more of fluorine (F), tetrafluoromethane (CF4), ozone (O2), or octafluorocyclobutane (C4F8), or the like). In some embodiments, the mask 1302 may comprise a photosensitive material (e.g., photoresist), a hard mask, or the like.

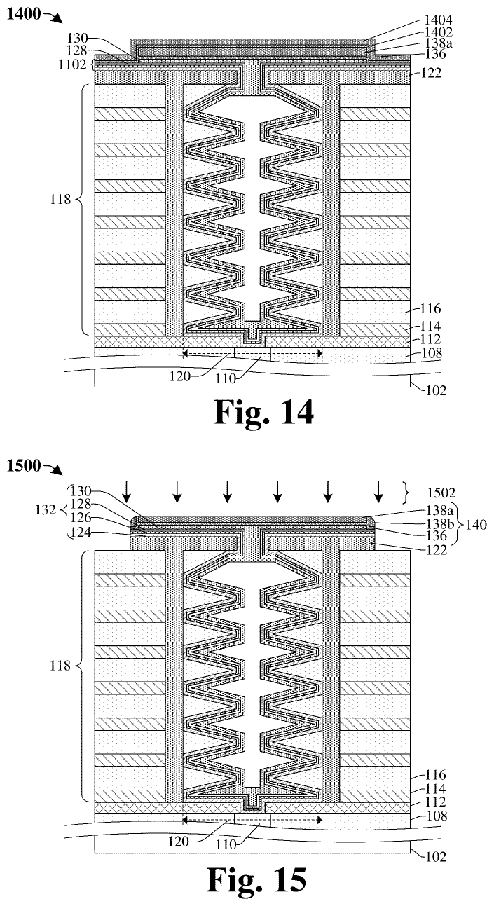

As shown in cross-sectional view 1400 of FIG. 14, a third passivation layer 1402 and a fourth passivation layer 1404 are formed over the second passivation layer 138a. In some embodiments, the third passivation layer 1402 may comprise a same material as the first passivation layer 136 and the fourth passivation layer 1404 may comprise a same material as the second passivation layer 138a. In some embodiments, the third passivation layer 1402 and the fourth passivation layer 1404 may each be formed by one or more deposition processes (e.g., a PVD process, a CVD process, a PE-CVD process, an ALD process, or the like).

As shown in the cross-sectional view 1500 of FIG. 15, an etch process is performed on the fourth passivation layer (1404 of FIG. 14), the third passivation layer (1402 of FIG. 14), the etch stop structure 122, and at least a portion of the stack of capacitor layers (1102 of FIG. 14) to define a capping structure 140 and a capacitor structure 132. The capping structure 140 comprises the first passivation layer 136, the second passivation layer 138a, and sidewall spacers 138b. In some embodiments, the etch process may be performed using one or more etchants 1502 which may comprise a dry etchant (e.g., a reactive ion etching (RIE) etchant, a plasma etchant, or the like). In some embodiments, the one or more etchants 1502 may have an etching chemistry comprising one or more of fluorine (F), tetrafluoromethane (CF4), ozone (O2), or octafluorocyclobutane (C4F8), or the like). The etch process may, for example, be or comprise a blanket etch.

As shown in the cross-sectional view 1600 of FIG. 16, a first upper dielectric layer 144 is formed over the capping structure 140 and the dielectric structure 118. In some embodiments, the first upper dielectric layer 144 may be formed by way of one or more deposition processes (e.g., a PVD process, a CVD process, a PE-CVD process, an ALD process, or the like).

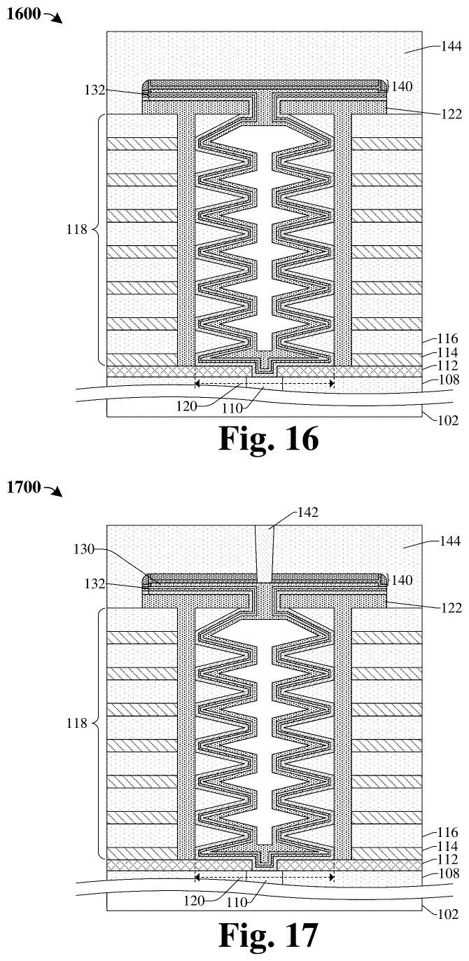

As shown in the cross-sectional view 1700 of FIG. 17, an upper interconnect via 142 is formed within the first upper dielectric layer 144. The upper interconnect via 142 extends though the first upper dielectric layer 144 and the capping structure 140 to contact the second conductive layer 130. In some embodiments, the upper interconnect via 142 may be formed by selectively etching the first upper dielectric layer 144 to define a trench within the first upper dielectric layer 144, forming a conductive material (e.g., copper, aluminum, etc.) within the trench, and performing a planarization process (e.g., a chemical mechanical planarization (CMP) process) to remove excess of the conductive material from over the first upper dielectric layer 144.

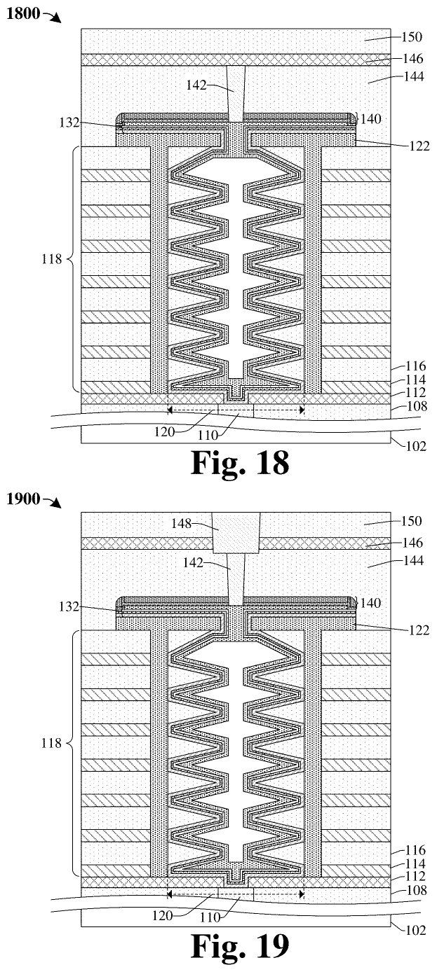

As shown in the cross-sectional view 1800 of FIG. 18, an upper etch stop layer 146 and a second upper dielectric layer 150 are formed over the first upper dielectric layer 144. In some embodiments, the upper etch stop layer 146 may, for example, be or comprise silicon nitride, silicon carbide, silicon oxynitride, silicon oxycarbide, or any combination of the foregoing, or another suitable dielectric material. The second upper dielectric layer 150 may, for example, be or comprise and oxide (e.g., silicon dioxide) or some other dielectric material. In some embodiments, the upper etch stop layer 146 and the second upper dielectric layer 150 may each be formed by way of one or more deposition processes (e.g., a PVD process, a CVD process, a PE-CVD process, an ALD process, or the like).

As shown in the cross-sectional view 1900 of FIG. 19, an upper interconnect wire 148 is formed within the second upper dielectric layer 150 and the top etch stop layer 146 to contact the upper interconnect via 142. In some embodiments, the upper interconnect wire 148 may be formed by selectively etching the upper etch stop layer 146 and the second upper dielectric layer 150 to define a trench within the upper etch stop layer 146 and the second upper dielectric layer 150, forming a conductive material (e.g., copper, aluminum, etc.) within the trench, and performing a planarization process (e.g., a chemical mechanical planarization (CMP) process) to remove excess of the conductive material from over the second upper dielectric layer 150.

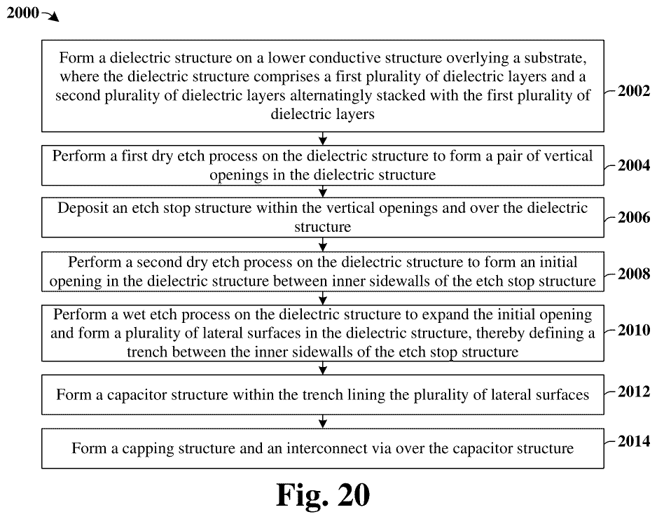

FIG. 20 illustrates a flow diagram of some embodiments of a method of forming an integrated chip having a capacitor structure disposed within a trench of a dielectric structure and an etch stop structure in the dielectric structure and around the trench.

While the disclosed method 2000 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2002, a dielectric structure is formed on a lower conductive structure overlying a substrate. The dielectric structure comprises a first plurality of dielectric layers and a second plurality of dielectric layers alternatingly stacked with the first plurality of dielectric layers. FIG. 6 illustrates a cross-sectional view 600 of some embodiments corresponding to act 2002.

At act 2004, a first dry etch process is performed on the dielectric structure to from a pair of vertical openings in the dielectric structure. FIG. 7 illustrates a cross-sectional view 700 of some embodiments corresponding to act 2004.

At act 2006, an etch stop structure is deposited in the vertical openings and over the dielectric structure. FIG. 8 illustrates a cross-sectional view 800 of some embodiments corresponding to act 2006.

At act 2008, a second dry etch process is performed on the dielectric structure to form an initial opening in the dielectric structure between inner sidewalls of the etch stop structure. FIG. 9 illustrates a cross-sectional view 900 of some embodiments corresponding to act 2008.

At act 2010, a wet etch process is performed on the dielectric structure to expand the initial opening and form a plurality of lateral surfaces in the dielectric structure, thereby defining a trench between the inner sidewalls of the etch stop structure. FIG. 10 illustrates a cross-sectional view 1000 of some embodiments corresponding to act 2010.

At act 2012, a capacitor structure is formed within the trench lining the plurality of lateral surfaces. FIG. 11 illustrates a cross-sectional view 1100 of some embodiments corresponding to act 2012.

At act 2014, a capping structure and an interconnect via are formed over the capacitor structure. FIGS. 12-17 illustrate cross-sectional views 1200-1700 of some embodiments corresponding to act 2014.

Accordingly, in some embodiments, the present disclosure relates to an integrated chip having a capacitor structure disposed in a trench of a dielectric structure and an etch stop structure in the dielectric structure and on opposing sides of the trench.

In some embodiments, the present disclosure relates to an integrated chip. The integrated chip includes a dielectric structure over a substrate, the dielectric structure having a first plurality of dielectric layers and a second plurality of dielectric layers alternatingly stacked with the first plurality of dielectric layers, the dielectric structure having a plurality of lateral surfaces that at least partially define a plurality of lateral recesses vertically aligned with the first plurality of dielectric layers; a capacitor structure arranged on the plurality of lateral surfaces and having a first conductive layer, a second conductive layer, and a capacitor dielectric layer between the first and second conductive layers; and an etch stop structure in the dielectric structure and vertically extending from a top surface of the dielectric structure to a bottom dielectric layer in the first plurality of dielectric layers, the etch stop structure laterally wraps around the capacitor structure and abuts the plurality of lateral surfaces.

In other embodiments, the present disclosure relates to a method of forming an integrated chip. The method includes forming a first conductive structure over a substrate; forming a dielectric structure over the first conductive structure, the dielectric structure having a first plurality of dielectric layers alternatingly stacked with a second plurality of dielectric layers; forming an etch stop structure in the dielectric structure, the etch stop structure having opposing inner sidewalls disposed on opposing sides of an inner segment of the dielectric structure, the etch stop structure separates the inner segment from an outer segment of the dielectric structure; performing an etching process on the dielectric structure to form a trench in the inner segment of the dielectric structure; and forming a capacitor structure in the trench, the capacitor structure having a plurality of protrusions extending laterally from a middle region of the trench to an individual sidewall in the opposing inner sidewalls of the etch stop structure.

In yet other embodiments, the present disclosure relates to a method of forming an integrated chip. The method includes forming a first conductive structure over a substrate; forming a dielectric structure over the first conductive structure, the dielectric structure having a first plurality of dielectric layers having a first material interleaved between a second plurality of dielectric layers having a second material different from the first material; performing a first etching process on the dielectric structure to form a pair of first openings in the dielectric structure and on opposing sides of the first conductive structure; forming an etch stop structure in the pair of first openings; performing a second etching process on the dielectric structure to form a second opening between opposing sidewalls of the etch stop structure and over the first conductive structure; performing a third etching process on the dielectric structure to expand the second opening and form a plurality of lateral surfaces in the second plurality of dielectric layers that at least partially define a trench, the plurality of lateral surfaces are vertically stacked with one another and abut the etch stop structure; and forming a first conductive layer, a capacitor dielectric layer, and a second conductive layer in the trench and along the plurality of lateral surfaces.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a dielectric structure over a substrate, wherein the dielectric structure comprises a first plurality of dielectric layers and a second plurality of dielectric layers alternatingly stacked with the first plurality of dielectric layers, wherein the dielectric structure comprises a plurality of lateral surfaces at least partially defining a plurality of lateral recesses vertically aligned with the first plurality of dielectric layers;
a capacitor structure arranged on the plurality of lateral surfaces and comprising a first conductive layer, a second conductive layer, and a capacitor dielectric layer between the first and second conductive layers; and
an etch stop structure in the dielectric structure and vertically extending from a top surface of the dielectric structure to a bottom dielectric layer in the first plurality of dielectric layers, wherein the etch stop structure laterally wraps around the capacitor structure and abuts the plurality of lateral surfaces.

2. The integrated chip of claim 1, wherein the capacitor structure continuously extends along the plurality of lateral surfaces to a sidewall of the etch stop structure.

3. The integrated chip of claim 1, wherein the second plurality of dielectric layers comprise a plurality of lateral protrusions arranged on a sidewall of the etch stop structure, wherein the plurality of lateral surfaces are surfaces of the plurality of lateral protrusions, and wherein adjacent lateral protrusions in the plurality of lateral protrusions are vertically separated from one another by a vertical distance that is equal to or greater than a thickness of a corresponding dielectric layer in the first plurality of dielectric layers.

4. The integrated chip of claim 1, wherein in cross-sectional view the etch stop structure comprises a pair of vertical segments arranged on opposing sides of the capacitor structure, and in top view the etch stop structure is ring shaped and extends around an outer perimeter of the capacitor structure.

5. The integrated chip of claim 4, wherein a lateral thickness of an individual vertical segment in the pair of vertical segments is greater than a thickness of the first conductive layer and a thickness of the second conductive layer.

6. The integrated chip of claim 1, wherein the etch stop structure is coupled to the first conductive layer.

7. The integrated chip of claim 1, wherein the etch stop structure comprises titanium nitride, tungsten, or tantalum.

8. The integrated chip of claim 1, wherein in cross-sectional view the etch stop structure comprises a pair of horizontal segments arranged on opposing sides of a vertical segment of the capacitor structure, wherein the pair of horizontal segments overlie the dielectric structure and a lower segment of the capacitor structure in the dielectric structure.

9. A method for forming an integrated chip, comprising:
forming a first conductive structure over a substrate;
forming a dielectric structure over the first conductive structure, wherein the dielectric structure comprises a first plurality of dielectric layers alternatingly stacked with a second plurality of dielectric layers;
forming an etch stop structure in the dielectric structure, wherein the etch stop structure comprises opposing inner sidewalls disposed on opposing sides of an inner segment of the dielectric structure, wherein the etch stop structure separates the inner segment from an outer segment of the dielectric structure;
performing an etching process on the dielectric structure to form a trench in the inner segment of the dielectric structure; and
forming a capacitor structure in the trench, wherein the capacitor structure comprises a plurality of protrusions extending laterally from a middle region of the trench to an individual sidewall in the opposing inner sidewalls of the etch stop structure.

10. The method of claim 9, wherein the etching process defines a plurality of surfaces in the second plurality of dielectric layers that extend from the middle region of the trench to the etch stop structure.

11. The method of claim 9, wherein the etching process removes inner regions of the first plurality of dielectric layers from the inner segment of the dielectric structure.

12. The method of claim 11, wherein the etch stop structure comprises outer opposing sidewalls in the dielectric structure, and wherein outer regions of the first plurality of dielectric layers contact the outer opposing sidewalls of the etch stop structure.

13. The method of claim 9, wherein a height of the capacitor structure is greater than a height of the etch stop structure.

14. The method of claim 9, further comprising:
forming a capping structure over the capacitor structure, wherein the capping structure comprises a passivation layer over the capacitor structure and a pair of sidewall spacers on opposing sides of the passivation layer.

15. The method of claim 9, further comprising:
forming an upper dielectric layer over the capacitor structure; and
forming a second conductive structure within the upper dielectric layer, wherein the second conductive structure is coupled to the capacitor structure.

16. A method for forming an integrated chip comprising:
forming a first conductive structure over a substrate;
forming a dielectric structure over the first conductive structure, wherein the dielectric structure comprises a first plurality of dielectric layers having a first material interleaved between a second plurality of dielectric layers having a second material different from the first material;
performing a first etching process on the dielectric structure to form a pair of first openings in the dielectric structure and on opposing sides of the first conductive structure;
forming an etch stop structure in the pair of first openings;
performing a second etching process on the dielectric structure to form a second opening between opposing sidewalls of the etch stop structure and over the first conductive structure;
performing a third etching process on the dielectric structure to expand the second opening and form a plurality of lateral surfaces in the second plurality of dielectric layers that at least partially define a trench, wherein the plurality of lateral surfaces are vertically stacked with one another and abut the etch stop structure; and
forming a first conductive layer, a capacitor dielectric layer, and a second conductive layer in the trench and along the plurality of lateral surfaces.

17. The method of claim 16, wherein during the third etching process the first plurality of dielectric layers have a greater etching rate than the second plurality of dielectric layers.

18. The method of claim 17, wherein during the third etching process the second plurality of dielectric layers have a greater etching rate than the etch stop structure.

19. The method of claim 16, wherein the second etching process comprises a dry etch and the third etching process comprises a wet etch.

20. The method of claim 16, wherein the plurality of lateral surfaces define a plurality of protrusions in the second plurality of dielectric layers that extend from the etch stop structure toward a middle region of the trench.
